(19) United States
(12) Patent Application Publication
(10) Pub. No.: US 2025/0059050 A1
(43) Pub. Date: Feb. 20, 2025

(54) COLLOIDAL SILICA AND PRODUCTION METHOD THEREFOR

(71) Applicant: FUSO CHEMICAL CO., LTD., Osaka-shi, Osaka (JP)

(72) Inventors: Chiharu Nakano, Fukuchiyama-shi, Kyoto (JP); Fumika Kojima, Fukuchiyama-shi, Kyoto (JP); Takahiro Tashima, Fukuchiyama-shi, Kyoto (JP); Shuta Ozawa, Fukuchiyama-shi, Kyoto (JP); Toshiki Chiba, Fukuchiyama-shi, Kyoto (JP)

(73) Assignee: FUSO CHEMICAL CO., LTD., Osaka-shi, Osaka (JP)

(21) Appl. No.: 18/722,765

(22) PCT Filed: Dec. 23, 2021
(86) PCT No.: PCT/JP2021/047847

§ 371 Date: Jun. 21, 2024

(51) Int. Cl. C01B 33/141; C09K 3/14; H01L 21/304

(52) U.S. Cl. CPC C01B 33/141; C09K 3/1463; H01L 21/304; C01P 2004/64

(57) ABSTRACT

A colloidal silica comprising water and silica particles, wherein the average particle size of the silica particles is 60 to 130 nm, and the content of coarse silica particles with a particle size of 0.2 μm or more among the silica particles is 10,000,000 particles/mL or less at a silica particle concentration of 1 mass.

### TECHNICAL FIELD

The present invention relates to colloidal silica and a method for producing the colloidal silica.

### BACKGROUND ART

In chemical mechanical polishing processes in semiconductor processing, nanometer-level smoothing of a substrate surface after polishing is required. Insufficient smoothing of a substrate surface, i.e., a rough substrate surface after polishing, causes disconnection and short circuits of wiring, resulting in the loss of reliability of the electrical connectivity of semiconductors, which becomes a critical functional defect.

In particular, in the progress of miniaturization of semiconductor line widths, there is a demand for even more precise smoothing of substrate surfaces after polishing.

The roughness of a substrate surface after polishing is known to be affected by the particle size of the abrasive grains contained in a polishing slurry, and typically, the larger the particle size of abrasive grains, the worse the surface roughness after polishing (Non-patent Literature (NPL) 1). Further, the addition of submicron-sized coarse particles to a polishing slurry containing silica nanoparticles as abrasive grains is known to deteriorate the roughness of a substrate surface after polishing (NPL 2).

Given the above, Patent Literature (PTL) 1 discloses setting the reaction conditions of the hydrolysis and polycondensation of alkoxysilane to specific conditions in the production of colloidal silica to thus produce colloidal silica containing fewer coarse particles with a particle size of 10 μm or more.

PTL 2 and PTL 3 disclose a method for removing submicron-sized coarse particles by filtering the produced colloidal silica through a precision filter.

However, in terms of colloidal silica in which the main particles have an average particle size of 60 nm or more, it is extremely difficult to effectively remove coarse particles with a particle size of 0.2 μm or more. Even with the methods disclosed in the above patent documents, it is hard to consider that coarse particles can be effectively removed.

### CITATION LIST

### Patent Literature

NPL 1: Lee M. Cook (2001) Chemical Processes in Glass Polishing
NPL 2: G. B. Basim et al. (2000) Effect of Particle Size of Chemical Mechanical Polishing Slurries for Enhanced Polishing with Minimal Defects
PTL 1: JP2012-6781A
PTL 2: JP2019-157121A
PTL 3: JP6751578B

### SUMMARY OF INVENTION

### Technical Problem

In view of the above circumstances, an object of the present invention is to provide colloidal silica that can be used as abrasive grains of a polishing slurry that is capable of reducing the surface roughness of polished surfaces in chemical mechanical polishing processes, and to provide a method for producing the colloidal silica.

### Solution to Problem

As a result of extensive research to solve the above problem, the present inventors have found that colloidal silica in which the average particle size is 60 to 130 nm and the amount of coarse particles of 0.2 μm or more is reduced to equal to or less than a specified amount can be produced by setting various conditions, such as the alkaline catalyst concentration in the mother liquor, to specific conditions. The present inventors have further conducted research based on the above findings and completed the present invention.

More specifically, the present invention provides the following colloidal silica and method for producing the colloidal silica.

Item 1.

A colloidal silica comprising water and silica particles,
wherein
the average particle size of the silica particles is 60 to 130 nm, and
the content of coarse silica particles with a particle size of 0.2 μm or more among the silica particles is 10,000,000 particles/mL or less at a silica particle concentration of 1 mass %.

Item 2.

A polishing composition comprising the colloidal silica of Item 1.

Item 3.

A method for producing colloidal silica, comprising
injecting an alkoxysilane solution containing an alkoxysilane and an alcohol into a mother liquor containing an alcohol, an alkaline catalyst, and water under the following reaction conditions (1) to (3) to obtain a reaction liquid:
(1) alkaline catalyst concentration in the mother liquor: 0.40 mol/L or more,
(2) water content in the reaction liquid: 4 mol or more per mole of the injection amount of alkoxysilane, and
(3) alcohol concentration in the alkoxysilane solution: 5.0 mol/L or more.

### Advantageous Effects of Invention

The use of the colloidal silica of the present invention described above as abrasive grains for a polishing slurry is expected to enable reduction of surface roughness of polished surfaces in chemical mechanical polishing. Further, the method for producing colloidal silica of the present invention described above enables production of colloidal silica with reduced coarse particles.

### DESCRIPTION OF EMBODIMENTS

### 1. Colloidal Silica

The colloidal silica of the present invention comprises water and silica particles. The colloidal silica of the present invention may also comprise substances other than water and silica particles as long as the effect and purpose are not impaired. It is also a preferable embodiment that the colloidal silica of the present invention consists of water and silica particles.

The average particle size of the silica particles contained in the colloidal silica of the present invention is 60 nm or more, preferably 80 nm or more, and more preferably 110 nm or more. If the average particle size of the silica particles is less than 60 nm, a sufficient polishing rate cannot be obtained.

Further, the average particle size of the silica particles contained in the colloidal silica is 130 nm or less. If the average particle size of the silica particles exceeds 130 nm, there is an increased risk that the surface roughness of polished surfaces will not be sufficiently reduced with the use of the colloidal silica of the present invention in chemical mechanical polishing.

The average particle size of the silica particles can be measured and calculated according to common methods, without particular limitation. For example, dynamic light scattering may be used for the measurement.

The content of coarse particles contained in the colloidal silica of the present invention is 10,000,000 particles/mL or less, preferably 9,000,000 particles/mL or less, and more preferably 8,000,000 particles/mL or less, at a silica particle concentration of 1 mass %. If the amount of coarse particles exceeds 10,000,000 particles/mL at a silica particle concentration of 1 mass %, there is an increased risk that the surface roughness of polished surfaces will not be sufficiently reduced with the use of the colloidal silica of the present invention in chemical mechanical polishing.

The lower limit of the content of coarse particles contained in the colloidal silica is not particularly limited, and is, for example, 1,000 particles/mL at a silica particle concentration of 1 mass %. Of course, it is also preferable that no coarse particles are contained (0 particles/mL).

As used herein, the “coarse particles” stated above are defined as silica particles with a particle size of 0.2 μm or more contained in colloidal silica.

The number of coarse particles at a silica particle concentration of 1 mass % can be measured by adding water (preferably ultrapure water) to colloidal silica to adjust the silica particle concentration to 1 mass %, and then measuring the number of coarse particles with a particle size of 0.2 μm or more with a particle size distribution analyzer or the like.

The BET specific surface area of the silica particles contained in the colloidal silica is preferably 15 m²/g or more, more preferably 20 m²/g or more, and even more preferably 25 m²/g or more. The BET specific surface area of the silica particles is preferably 110 m²/g or less, more preferably 100 m²/g or less, and even more preferably 90 m²/g or less.

The BET specific surface area of silica particles can be measured by using a sample obtained by pre-drying colloidal silica on a hot plate, followed by heating at 800° C. for 1 hour.

As described above, the colloidal silica of the present invention comprises water and silica particles. However, it is also preferable that the colloidal silica comprises an organic solvent as a dispersion medium for the silica particles, in addition to water.

The organic solvents are usually hydrophilic organic solvents. Examples include alcohols (e.g., methanol, ethanol, n-propanol, isopropanol, ethylene glycol, propylene glycol, and 1,4-butanediol), ketones (e.g., acetone and methyl ethyl ketone), and esters (e.g., ethyl acetate). These organic solvents may be used alone or in a combination of two or more.

The content of the silica particles in the colloidal silica is preferably 5 masse or more, more preferably 8 masse or more, even more preferably 10 mass % or more, and still more preferably 12 mass or more, for the reason that the amounts of additives for blending are easily adjusted when the colloidal silica is used as a starting material of a polishing composition.

### 2. Polishing Composition

The present invention encompasses an invention relating to a polishing composition comprising the colloidal silica described above. The polishing composition can be suitably used for chemical mechanical polishing.

The polishing composition of the present invention may further comprise additives without particular limitation, as long as the polishing composition comprises the colloidal silica of the present invention described above. Examples of additives include diluents, oxidants, pH adjusters, corrosion inhibitors, stabilizers, and surfactants. These may be used alone or in a combination of two or more.

The content of the silica particles in the polishing composition is, for example, 0.01 to 20 mass %, more preferably 0.05 to 10 mass %, and even more preferably 0.1 to 5 mass's.

### 3. Method for Producing Colloidal Silica

The present invention encompasses an invention relating to a method for producing the colloidal silica described above.

The method for producing colloidal silica of the present invention comprises the step of injecting an alkoxysilane solution containing an alkoxysilane and an alcohol into a mother liquor containing an alcohol, an alkaline catalyst, and water to obtain a reaction liquid (also referred to below as “step 1”).

### 3.1. Step 1

Step 1 is carried out under the following reaction conditions (1) to (3):
(1) alkaline catalyst concentration in the mother liquor: 0.40 mol/L or more,
(2) water content in the reaction liquid: 4 mol or more per mole of the injection amount of alkoxysilane, and
(3) alcohol concentration in the alkoxysilane solution: 5.0 mol/L or more.

The alcohol contained in the mother liquor is not particularly limited and may be any known alcohol used in the relevant technical field. Specific examples include methanol, ethanol, n-propanol, isopropanol, ethylene glycol, propylene glycol, and 1,4-butanediol. These may be used alone or in a combination of two or more.

The concentration of the alcohol contained in the mother liquor is preferably 10.0 mol/L or more, more preferably 13.0 mol/L or more, and even more preferably 15.0 mol/L mol/L or more, so as to prevent the local occurrence of the hydrolysis reaction of alkoxysilane and suppress the formation of gel-like matter. Further, the concentration of the alcohol contained in the mother liquor is preferably 23.0 mol/L or less, more preferably 22.5 mol/L or less, and even more preferably 22.0 mol/L or less, so as to prevent unreacted alkoxysilane from remaining.

The alkaline catalyst is also not particularly limited and may be any known alkaline catalyst used in the relevant technical field. To avoid metal impurity contamination, the alkaline catalyst is preferably an organic base catalyst that does not contain a metal component, and particularly preferably a nitrogen-containing organic base catalyst. Examples of such organic base catalysts include ethylenediamine, diethylenetriamine, triethylenetetramine, ammonia, urea, monoethanol amine, diethanol amine, triethanol amine, tetramethylammonium hydroxide (TMAH), tetramethylguanidine, 3-ethoxypropylamine, dipropylamine, and triethylamine. These may be used alone or in a combination of two or more. Ammonia, which has excellent catalytic activity and high volatility, and which can be easily removed in a subsequent step, is preferred. From the standpoint of increasing the density of silica particles, it is preferable to select an organic base catalyst with a boiling point of 90° C. or higher so as to avoid volatilization even when the reaction temperature is increased, and it is more preferable to use at least one member selected from tetramethylammonium hydroxide and 3-ethoxypropylamine.

The content of the alkaline catalyst in the mother liquor is 0.40 mol/L or more, preferably 0.41 mol/L or more, and more preferably 0.42 mol/L or more. If the content of the alkaline catalyst in the mother liquor is less than 0.40 mol/L, the stability of the nuclear particles formed during the synthesis process of silica particles decreases, the aggregation of the nuclear particles progresses, and the amount of coarse silica particles of 0.2 μm or more increases.

The upper limit of the content of the alkaline catalyst in the mother liquor is preferably 0.90 mol/L or less, and more preferably 0.80 mol/L mol/L or less, so as to prevent the particle size of the synthesized silica particles from excessively increasing by preventing the hydrolysis and dehydration condensation reaction of alkoxysilane from proceeding excessively.

The content of the alkaline catalyst in the mother liquor is preferably 0.10 mol or more, and more preferably 0.20 mol or more, per mole of the injection amount of alkoxysilane. By setting the content of the alkaline catalyst in the mother liquor to 0.10 mol or more per mole of the injection amount of alkoxysilane, the formation of particle aggregation is suppressed, and the amount of coarse silica particles of 0.2 μm or more is further reduced. However, when the alkaline catalyst solution described later is also injected into the mother liquor in step 1, the total amount of the alkaline catalyst contained in the mother liquor and the alkaline catalyst solution is preferably 0.10 mol or more, and more preferably 0.20 mol or more, per mole of the injection amount of alkoxysilane.

The content of the alkaline catalyst in the mother liquor is preferably 1.20 mol or less, and more preferably 1.10 mol or less, per mole of the injection amount of alkoxysilane. By setting the content of the alkaline catalyst in the mother liquor to 1.20 mol or less per mole of the injection amount of alkoxysilane, the hydrolysis reaction of alkoxysilane can be allowed to proceed slowly, and the occurrence of particle aggregation is further reduced. However, when the alkaline catalyst solution described later is also injected into the mother liquor in step 1, the total amount of the alkaline catalyst contained in the mother liquor and the alkaline catalyst solution is preferably 1.20 mol or less, and more preferably 1.10 mol or less, per mole of the injection amount of alkoxysilane.

The content of water in the mother liquor is preferably 1.00 mol/L or more, and more preferably 2.00 mol/L or more. By setting the water content in the mother liquor to 1.00 mol/L or more, the amount of unreacted alkoxysilane remaining is reduced, the dispersion stability of the synthesized silica particles is improved, and the occurrence of particle aggregation is further suppressed.

Further, the content of water in the mother liquor is preferably 15.00 mol/L or less, and more preferably 14.00 mol/L or less. By setting the water content in the mother liquor to 15.00 mol/L or less, the hydrolysis reaction of alkoxysilane can be allowed to proceed slowly, and the occurrence of particle aggregation is further reduced.

The content of water in the mother liquor is 4 mol or more, preferably 4.5 mol or more, and more preferably 5 mol or more, per mole of the injection amount of alkoxysilane. If the total amount of water contained in the mother liquor and the alkoxysilane solution is less than 4 mol per mole of the injection amount of alkoxysilane, unreacted alkoxysilane will remain, which serves as a cause of deterioration of dispersion stability of the synthesized silica particles. However, when the alkaline catalyst solution described later is also injected into the mother liquor in step 1, the total amount of water contained in the mother liquor and the alkaline catalyst solution is 4 mol or more, preferably 4.5 mol or more, and more preferably 5 mol or more, per mole of the injection amount of alkoxysilane.

The content of water in the mother liquor is preferably 12.0 mol or less, and more preferably 11.0 mol or less, per mole of the injection amount of alkoxysilane. By setting the water content in the mother liquor to 12.0 mol or less per mole of the injection amount of alkoxysilane, the hydrolysis reaction of alkoxysilane can be allowed to proceed slowly, and the occurrence of particle aggregation is further reduced. However, when the alkaline catalyst solution described later is also injected into the mother liquor in step 1, the total amount of water contained in the mother liquor and the alkaline catalyst solution is preferably 12.0 mol or less, and more preferably 11.0 mol or less, per mole of the injection amount of alkoxysilane.

The alcohol contained in the alkoxysilane solution may be the same as or similar to the alcohol used for the mother liquor described above. These organic solvents may be used alone or in a combination of two or more. The organic solvent for use here may be the same organic solvent used for the mother liquor or may be a different organic solvent.

The alcohol concentration in the alkoxysilane solution is 5.0 mol/L or more, and preferably 6.0 mol/L or more. If the alcohol concentration is less than 5.0 mol/L, the hydrolysis and dehydration condensation reaction of alkoxysilane proceed locally, and the amount of coarse silica particles of 0.2 μm or more increases.

The upper limit of the alcohol concentration in the alkoxysilane solution is not particularly limited and is preferably, for example, 23 mol/L or less.

Examples of the alkoxysilane contained in the alkoxysilane solution include tetra-C₁₋₈ alkoxysilanes, such as tetramethoxysilane, tetraethoxysilane, and tetraisopropoxysilane. These may be used alone or in a combination of two or more. Of these, tetra-C₁₋₄ alkoxysilanes are preferred, and tetramethoxysilane and/or tetraethoxysilane are even more preferred.

The alkoxysilane concentration in the alkoxysilane solution is preferably 2.0 mol/L or more, and more preferably 4.0 mol/L or more. Similarly, the alkoxysilane concentration is preferably 5.4 mol/L or less, and more preferably 5.2 mol/L or less. By adopting such a configuration, the colloidal silica can be produced with high productivity while suppressing the formation of coarse silica particles of 0.2 μm or more.

In addition to the alkoxysilane solution, it is preferable to also inject an alkaline catalyst solution into the mother liquor. The alkaline catalyst contained in the alkaline catalyst solution can be the same as or similar to the alkaline catalyst used for the mother liquor.

The amount of the alkaline catalyst contained in the alkaline catalyst solution is preferably 2.0 mass % or more, more preferably 2.5 mass % or more, and even more preferably 3.0 mass % or more. Further, the amount of the alkaline catalyst is preferably 10.0 masse or less, more preferably 9.0 mass % or less, and even more preferably 8.0 mass, or less. By adopting such a configuration, unreacted alkoxysilane can be prevented from remaining while suppressing the occurrence of particle aggregation.

Suitable solvents for use for the alkaline catalyst in the alkaline catalyst solution may be an alcohol, water, and the like, without particular limitation. Of these, it is preferable to use water.

The injection rate of alkoxysilane in step 1 is preferably 0.90 parts by mass/min or less, and more preferably 0.85 parts by mass/min or less, per 100 parts by mass of the mother liquor, so as to suppress a local increase in the alkoxysilane concentration and suppress the occurrence of particle aggregation. Further, the injection rate of alkoxysilane in step 1 is preferably 0.10 parts by mass/min or more per 100 parts by mass of the mother liquor, so as to improve productivity. When the alkaline catalyst solution is used, the alkoxysilane solution and the alkaline catalyst solution are preferably injected simultaneously into the mother liquor.

The reaction temperature at which the reaction is allowed to proceed in terms of the reaction liquid is preferably 15° C. or higher, and more preferably 18° C. or higher. By adopting such a configuration, the stability of the nuclear particles formed during the synthesis process of silica particles is improved, the aggregation of nuclear particles is suppressed, and the formation of coarse silica particles of 0.2 μm or more is suppressed.

The above reaction temperature is preferably 40° C. or lower, and more preferably 34° C. or lower. By adopting such a configuration, the reactivity of alkoxysilane can be suppressed, and excessive increase in the particle size can be prevented.

### 3.2. Step 2

It is also preferable that the method for producing colloidal silica of the present invention further comprises the step of replacing the liquid component in the reaction liquid obtained in step 1 with water (also referred to simply as “step 2”).

In step 2, known methods for replacement used in the related technical fields can be widely used, without particular limitation. Examples include a method in which water is added after distilling off of the reaction liquid obtained in step 1.

The embodiments of the present invention are described above. However, the present invention is not limited to these examples and can of course be implemented in various forms within the scope that does not deviate from the spirit of the present invention.

### EXAMPLES

The embodiments of the present invention will be described in more detail below with reference to Examples; however, the present invention is not limited to these Examples.

### Example 1

A mother liquor was produced by mixing 100 parts by mass of methanol, 11 parts by mass of ultrapure water, and 6 parts by mass of 28 mass % aqueous ammonia. An alkoxysilane solution was prepared by mixing 50 parts by mass of tetramethoxysilane and 14 parts by mass of methanol, relative to 100 parts by mass of the methanol used for the mother liquor. An alkaline catalyst solution was prepared by mixing 34 parts by mass of ultrapure water and 5 parts by mass of 28 mass % aqueous ammonia. The starting material solution and the alkaline catalyst solution were injected at a constant rate into the mother liquor for 60 minutes while maintaining the temperature of the mother liquor at 25° C. to obtain a reaction liquid. The alkaline catalyst concentration in the mother liquor was 0.68 mol/L. The alcohol concentration in the alkoxysilane solution was 6.5 mol/L. The total amount of water used in the reaction system was 8.9 mol per mole of the injection amount of tetramethoxysilane. While distilling off the solvent by heating, ultrapure water in an amount of 190 parts by mass, relative to 100 parts by mass of the obtained reaction liquid, was added to completely replace the solvent components with water while maintaining a constant volume, whereby colloidal silica was obtained.

### Example 2

A mother liquor was produced by mixing 100 parts by mass of methanol, 11 parts by mass of ultrapure water, and 6 parts by mass of 28 mass % aqueous ammonia. An alkoxysilane solution was prepared by mixing 50 parts by mass of tetramethoxysilane and 12 parts by mass of methanol, relative to 100 parts by mass of the methanol used for the mother liquor. An alkaline catalyst solution was prepared by mixing 34 parts by mass of ultrapure water and 5 parts by mass of 28 mass % aqueous ammonia. The starting material solution and the alkaline catalyst solution were injected at a constant rate into the mother liquor for 60 minutes while maintaining the temperature of the mother liquor at 25° C. to obtain a reaction liquid. The alkaline catalyst concentration in the mother liquor was 0.68 mol/L. The alcohol concentration in the alkoxysilane solution was 6.0 mol/L. The total amount of water used in the reaction system was 8.9 mol per mole of the injection amount of tetramethoxysilane. While distilling off the solvent by heating, ultrapure water in an amount of 190 parts by mass, relative to 100 parts by mass of the obtained reaction liquid, was added to completely replace the solvent components with water while maintaining a constant volume, whereby colloidal silica was obtained.

### Example 3

A mother liquor was produced by mixing 100 parts by mass of methanol, 30 parts by mass of ultrapure water, and 4 parts by mass of 28 mass % aqueous ammonia. An alkoxysilane solution was prepared by mixing 119 parts by mass of tetramethoxysilane and 32 parts by mass of methanol, relative to 100 parts by mass of the methanol used for the mother liquor. An alkaline catalyst solution was prepared by mixing 34 parts by mass of ultrapure water and 9 parts by mass of 28 mass& aqueous ammonia. The starting material solution and the alkaline catalyst solution were injected at a constant rate into the mother liquor for 150 minutes while maintaining the temperature of the mother liquor at 20° C. to obtain a reaction liquid. The alkaline catalyst concentration in the mother liquor was 0.43 mol/L. The alcohol concentration in the alkoxysilane solution was 6.5 mol/L. The total amount of water used in the reaction system was 5.2 mol per mole of the injection amount of tetramethoxysilane. While distilling off the solvent by heating, ultrapure water in an amount of 190 parts by mass, relative to 100 parts by mass of the obtained reaction liquid, was added to completely replace the solvent components with water while maintaining a constant volume, whereby colloidal silica was obtained.

### Comparative Example 1

A mother liquor was produced by mixing 100 parts by mass of methanol, 11 parts by mass of ultrapure water, and 6 parts by mass of 28 mass % aqueous ammonia. Tetramethoxysilane in an amount of 50 parts by mass, relative to 100 parts by mass of the methanol used for the mother liquor, was used as an alkoxysilane (the alkoxysilane was not dissolved in a solvent). An alkaline catalyst solution was prepared by mixing 34 parts by mass of ultrapure water and 5 parts by mass of 28 mass % aqueous ammonia. The starting material solution and the alkaline catalyst solution were injected at a constant rate into the mother liquor for 60 minutes while maintaining the temperature of the mother liquor at 25° C. to obtain a reaction liquid. The alkaline catalyst concentration in the mother liquor was 0.68 mol/L. The total amount of water used in the reaction system was 8.9 mol per mole of the injection amount of tetramethoxysilane. While distilling off the solvent by heating, ultrapure water in an amount of 190 parts by mass, relative to 100 parts by mass of the obtained reaction liquid, was added to completely replace the solvent components with water while maintaining a constant volume, whereby colloidal silica was obtained.

### Comparative Example 2

The colloidal silica of Comparative Example 1 was filtered through a precision filter with a filtration accuracy of 0.2 μm (SLF-002, produced by Roki Techno Co., Ltd.) to obtain colloidal silica of Comparative Example 2.

### Measurement of Average Particle Size

The colloidal silica of the Examples and Comparative Examples was independently diluted by adding a 0.3 masse citric acid aqueous solution to a silica particle concentration of 1.0 mass %. The diluted liquids were used as measurement samples. By using the measurement samples, the average particle size was measured by a dynamic light scattering method (ELSZ-2000, produced by Otsuka Electronics Co., Ltd.).

Measurement of Number of Coarse particles

The colloidal silica of the Examples and Comparative Examples was independently diluted by adding ultrapure water to a silica concentration of 1.0 mass %. The diluted liquids were used as measurement samples, and the number of coarse particles of 0.2 μm or more was measured using an AccuSizer FX-Nano produced by Particle Sizing Systems, Inc. The measurement conditions were as follows.

System Setup
Stirred Vessel Volume: 13.22 mL
Sample Loop Volume: 0.52 mL
Autodilution delay time: 3 sec
Normal Speed Flow Rate: 15 mL/min

### Sensor Setup Menu

FX-Nano HG Minimum Size: 0.15 μm
FX-Nano HG Maximum Size: 0.27 μm
FX-Nano HG Collection Time: 60 sec
HG Starting Concentration: 8000 #/mL

### Evaluation of Surface Roughness of Polished Surface

The colloidal silica of the Examples and Comparative Examples was independently diluted by adding ultrapure water to a silica concentration of 3.0 mass % to obtain polishing compositions. The obtained polishing compositions were each used under the following conditions to polish a 3 cm square silicon wafer with a silicon oxide film formed on its surface.
Polishing device: NF-300CMP, produced by Nano Factor Co., Ltd.
Polishing pad: IC1000IM Pad, produced by Nitta DuPont Incorporated
Slurry feed rate: 50 mL/min
Head rotation speed: 32 rpm
Platen rotation speed: 32 rpm
Polishing pressure: 4 psi
Polishing time: 2 min

The surface roughness of the polished surface of the wafers after polishing was evaluated using an atomic force microscope under the following conditions.
Atomic force microscope: SPM-9700HT, produced by Shimadzu Corporation
Cantilever: Micro Cantilever OMCL-AC240TS-R3, produced by Olympus Corporation
Observation mode: Dynamic
Scanning range: 3.0 μm square
Scanning speed: 1.00 Hz
Number of observation fields: five fields of view were observed per wafer after polishing.
Calculation method for surface roughness: the average root-mean-square roughness of five fields of view was calculated and used as the surface roughness of the polished surface.

Table 1 below indicates that the colloidal silica obtained in Example 1, Example 2, and Example 3 had an average particle size of 60 to 130 nm and contained a small amount of coarse particles with a particle size of 0.2 μm or more. Further, the results of the polishing test confirmed that the surface roughness of the polished surface was reduced when Example 1, Example 2, and Example 3 were used, compared with when Comparative Example 1 and Comparative Example 2 were used.

TABLE 1

| | | Example | | | Comparative Example | |
|---|---|---|---|---|---|---|
| Item | | Ex. 1 | Ex. 2 | Ex. 3 | Comp. Ex 1 | Comp. Ex. 2 |
| Mother | Solution amount, parts by mass | 100.00 | 100.00 | 100.00 | 100.00 | 100.00 |
| liquor | Alkaline catalyst concentration, mol/L | 0.68 | 0.68 | 0.43 | 0.68 | 0.68 |
| | Water concentration, mol/L | 5.74 | 5.74 | 11.25 | 5.74 | 5.74 |
| | Alcohol concentration, mol/L | 21.76 | 21.76 | 19.46 | 21.76 | 21.76 |
| Starting | Alkoxysilane concentration, mol/L | 5.000 | 5.124 | 5.000 | 6.767 | 6.767 |
| material | Alcohol concentration, mol/L | 6.5 | 6.0 | 6.5 | 0.0 | 0.0 |
| solution | Injection amount of alkoxysilane, parts by mass | 42.92 | 42.92 | 88.85 | 42.92 | 42.92 |
| | Injection rate of alkoxysilane, parts by mass/min | 0.72 | 0.72 | 0.59 | 0.72 | 0.72 |
| Alkaline | Alkaline catalyst concentration, wt % | 3.8 | 3.8 | 5.9 | 3.8 | 3.8 |
| catalyst | Injection amount, parts by mass | 33.91 | 33.91 | 32.56 | 33.91 | 33.91 |
| solution | Injection rate, parts by mass/min | 0.57 | 0.57 | 0.22 | 0.57 | 0.57 |
| Amount of water used in the reaction system, mol | | 8.9 | 8.9 | 5.2 | 8.9 | 8.9 |
| (per mole of the injection amount of alkoxysilane) | | | | | | |
| Reaction temperature, ° C. | | 25 | 25 | 20 | 25 | 25 |
| Physical | Secondary particle size (DLS), nm | 122.5 | 122.6 | 121.7 | 125.0 | 125.6 |
| properties | LPC (≥0.20 μm), #/mL | 7,159,090 | 7,194,885 | 8,004,416 | 18,409,114 | 113,231,261 |
| | (per 1 wt % of silica concentration) | | | | | |

| | | | | | |
|---|---|---|---|---|---|
| Surface roughness of polished surface, nm | 2.169 | 2.180 | 2.305 | 3.606 | 6.752 |

1. A colloidal silica comprising water and silica particles,
wherein
the average particle size of the silica particles is 60 to 130 nm, and
the content of coarse silica particles with a particle size of 0.2 μm or more among the silica particles is 10,000,000 particles/mL or less at a silica particle concentration of 1 mass %.

2. A polishing composition comprising the colloidal silica of claim 1.

3. A method for producing colloidal silica, comprising
injecting an alkoxysilane solution containing an alkoxysilane and an alcohol into a mother liquor containing an alcohol, an alkaline catalyst, and water under the following reaction conditions (1) to (3) to obtain a reaction liquid:
(1) alkaline catalyst concentration in the mother liquor: 0.40 mol/L or more,
(2) water content in the reaction liquid: 4 mol or more per mole of the injection amount of alkoxysilane, and
(3) alcohol concentration in the alkoxysilane solution: 5.0 mol/L or more.
